(19) United States
(12) Patent Application Publication
(10) Pub. No.: US 2025/0349459 A1
(43) Pub. Date: Nov. 13, 2025

(54) INDUCTIVE DEVICE FOR SURFACE MOUNTING

(71) Applicant: QUALCOMM Incorporated, San Diego, CA (US)

(72) Inventors: Kai LIU, San Diego, CA (US); Nosun PARK, San Diego, CA (US); Jonghae KIM, San Diego, CA (US)

(21) Appl. No.: 18/659,894

(22) Filed: May 9, 2024

(51) Int. Cl. H01F 27/28; H01F 27/32; H01L 23/00; H01L 23/522; H01L 25/16

(52) U.S. Cl. CPC H01F 27/2866; H01F 27/327; H01L 23/5223; H01L 23/5227; H01L 24/16; H01L 25/16; H01L 2224/16225; H01L 2924/19042

(57) ABSTRACT

Disclosed are techniques for a structure of an inductive device. In an aspect, an inductive device includes a first conductive structure, a second conductive structure, and a bond-wire structure. The first conductive structure has a first anchor portion and a first elongated portion. The second conductive structure has a second anchor portion and a second elongated portion. The bond-wire structure has a first bottom portion mounted on the first elongated portion, a second bottom portion mounted on the second elongated portion, and an arch portion between the first bottom portion and the second bottom portion. A coil structure of an inductor of the inductive device comprises the arch portion, the first elongated portion, and the second elongated portion.

### TECHNICAL FIELD

The present disclosure generally relates to an inductive device, and, more particularly, to an inductive device that is usable for surface mounting in conjunction with a power management integrated circuit (PMIC) and an integrated circuit (IC) package on a circuit board in an electronic device.

### BACKGROUND

Integrated circuit (IC) technology has achieved great strides in advancing computing power through miniaturization of electrical components. An IC may be implemented in the form of an IC chip that has a set of circuits integrated thereon. In some implementations, one or more IC chips can be physically carried and protected by an IC package, where various power and signal nodes of the one or more IC chips can be electrically coupled to respective conductive terminals of the IC package via conductive paths formed in a package substrate of the IC package. Various packaging technologies can be found in many electronic devices, including processors, servers, radio frequency (RF) integrated circuits, etc. Advanced packaging and processing techniques can be used to implement complex devices, such as multi-die devices and system on a chip (SOC) devices, which may include multiple function blocks, with each function block designed to perform a specific function, such as, for example, a microprocessor function, a graphics processing unit (GPU) function, a communications function (e.g., Wi-Fi, Bluetooth, and other communications), and the like.

In some applications, an IC package may be further mounted on a circuit board (e.g., a printed circuit board, or known as a PCB) of an electronic device. In some examples, a power management integrated circuit (PMIC) (e.g., in the form of another IC package) may be mounted on the PCB and configured to manage one or more power distribution networks (PDNs) for supplying power to the IC dies in the IC package. In some applications, the PMIC is configured to receive an external power supply at a higher voltage level (e.g., 5˜12 volts (V)) to an internal supply voltage at a lower voltage level (0.7˜1.0 V or 1.5˜2.5 V) for energizing the IC die(s) in the IC package.

In some applications, one or more passive devices may be electrically coupled to a conductive path carrying the internal supply voltage. In some examples, one or more capacitive devices may be electrically coupled to the conductive path carrying the internal supply voltage (e.g., between the conductive path carrying the internal supply voltage and another conductive path carrying a ground voltage) in order to stabilize a direct current (DC) voltage level of the internal supply voltage. In some examples, one or more inductive devices may be electrically coupled to the conductive path carrying the internal supply voltage (e.g., connected to the conductive path in series) in order to reduce the non-DC noises of (or coupled to by cross-talking) the internal supply voltage. In some examples, these passive devices may be implemented as surface mounted devices (SMDs) disposed on the PCB.

Accordingly, to further improve the performance and reduce the cost of an electronic device, there may be a need for an inductive device, usable in conjunction with a PMIC and an IC package on a circuit board in the electronic device, that is compatible with the form factor of an SMD for surface mounting, with at least comparable or greater inductance, reduced DC resistance, and reduced manufacturing complexity and/or costs.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an inductive device includes a first conductive structure having a first anchor portion and a first elongated portion, the first anchor portion corresponding to a first terminal of an inductor of the inductive device, and the first elongated portion having coupled to the first anchor portion at a first end portion; a second conductive structure having a second anchor portion and a second elongated portion, the second anchor portion corresponding to a second terminal of the inductor of the inductive device, and the second elongated portion coupled to the second anchor portion at a third end portion; and a bond-wire structure having a first bottom portion, a second bottom portion, and an arch portion between the first bottom portion and the second bottom portion, the first bottom portion being mounted on a second end portion of the first elongated portion, and the second bottom portion being mounted on a fourth end portion of the second elongated portion, wherein: a coil structure of the inductor of the inductive device comprises the arch portion, the first elongated portion, and the second elongated portion.

In an aspect, a method of manufacturing an inductive device includes mounting a first bottom portion of a bond-wire structure on a first conductive structure that has a first anchor portion and a first elongated portion, the first anchor portion corresponding to a first terminal of an inductor of the inductive device, and the first elongated portion coupled to the first anchor portion at a first end portion; and mounting a second bottom portion of the bond-wire structure on a second conductive structure that has a second anchor portion and a second elongated portion, the second anchor portion corresponding to a second terminal of the inductor of the inductive device, and the second elongated portion coupled to the second anchor portion at a third end portion, wherein: the bond-wire structure further includes an arch portion between the first bottom portion and the second bottom portion, the first bottom portion being mounted on a second end portion of the first elongated portion, and the second bottom portion being mounted on a fourth end portion of the second elongated portion, and a coil structure of the inductor of the inductive device comprises the arch portion, the first elongated portion, and the second elongated portion.

In an aspect, an electronic device includes an inductive device that comprises: a first conductive structure having a first anchor portion and a first elongated portion, the first anchor portion corresponding to a first terminal of an inductor of the inductive device, and the first elongated portion coupled to the first anchor portion at a first end portion; a second conductive structure having a second anchor portion and a second elongated portion, the second anchor portion corresponding to a second terminal of the inductor of the inductive device, and the second elongated portion coupled to the second anchor portion at a third end portion; and a bond-wire structure having a first bottom portion, a second bottom portion, and an arch portion between the first bottom portion and the second bottom portion, the first bottom portion being mounted on a second end portion of the first elongated portion, and the second bottom portion being mounted on a fourth end portion of the second elongated portion, wherein: a coil structure of the inductor of the inductive device comprises the arch portion, the first elongated portion, and the second elongated portion.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1 is a cross-sectional view of a portion of a circuit board assembly example, according to aspects of the disclosure.

FIG. 2 is a simplified layout view of a portion of a layout pattern of a circuit board, according to aspects of the disclosure.

FIG. 3 is a simplified perspective view of an example inductive device, according to aspects of the disclosure.

FIGS. 4A-4D show different views of the example inductive device of FIG. 3, according to aspects of the disclosure.

FIGS. 5A-5B show electrical characteristics of the example inductive device of FIG. 3, according to aspects of the disclosure.

FIGS. 6A-6E illustrate structures at various stages of manufacturing the example inductive device of FIG. 3, according to aspects of the disclosure.

FIGS. 7A-7C illustrate another example inductive device, according to aspects of the disclosure.

FIG. 8 illustrates a method of manufacturing an inductive device, according to aspects of the disclosure.

FIG. 9 illustrates various electronic devices that may include an inductive device described herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Various aspects relate generally to an inductive device for surface mounting, and to a method of manufacturing inductive device.

Particular aspects of the subject matter described in this disclosure can be implemented to realize one or more of the following potential advantages. In some examples, by forming a coil structure based on a bond-wire structure, the described techniques can be used to form an inductive device, usable in conjunction with a power management integrated circuit (PMIC) and an integrated circuit (IC) package on a circuit board in an electronic device, that is compatible with the form factor of an surface mounted device (SMD), with at least comparable or greater inductance, reduced direct current (DC) resistance, and reduced manufacturing complexity and/or costs.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

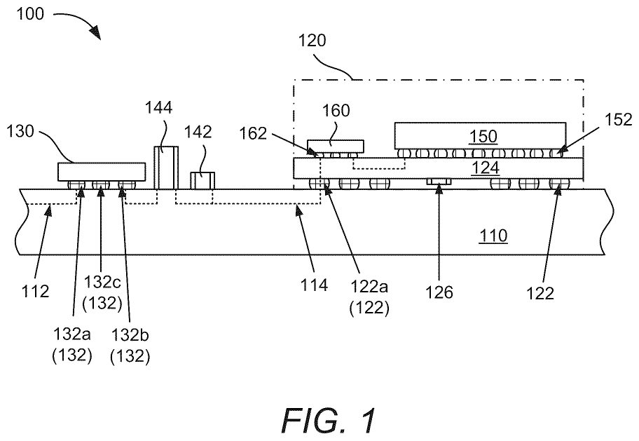

FIG. 1 is a cross-sectional view of a portion of a circuit board assembly example 100, according to aspects of the disclosure. In some aspects, FIG. 1 is a simplified cross-sectional view of the circuit board assembly example 100, and certain details and components of the circuit board assembly example 100 may be simplified or may not be depicted in FIG. 1.

As shown in FIG. 1, the circuit board assembly example 100 may include a printed circuit board (PCB) 110, an integrated circuit (IC) package 120 mounted on the PCB 110, and a power management integrated circuit (PMIC) 130 mounted on the PCB 110. In some aspects, the circuit board assembly example 100 may further include a capacitive device 142 and an inductive device 144 mounted on the PCB 110.

In some aspects, the PCB 110 may include layers of conductive patterns formed therein (not shown). In some aspects, the IC package 120 may be mounted on the PCB 110 through terminal structures 122 (e.g., solder bumps based on a controlled collapse of chip connection (C4) mounting method, also referred to as C4 bumps). In some aspects, the PMIC 130 may be mounted on the PCB 110 through terminal structures 132 (e.g., C4 bumps).

In some aspects, the IC package 120 may include a package substrate 124, a first IC die 150 mounted on an upper surface of the package substrate 124 through terminal structures 152 (e.g., solder bumps or copper pillar bumps), a second IC die 160 mounted on the upper surface of the package substrate 124 through terminal structures 162 (e.g., solder bumps or copper pillar bumps), and one or more passive devices 126 mounted on a lower surface of the package substrate 124. In some aspects, the first IC die 150 may include circuitry configured as a processor, a system on a chip, a memory, or a combination thereof. In some aspects, the second IC die 160 may include circuitry configured as an integrated voltage regulator (IVR).

In some aspects, the PMIC 130 may include a first power node (e.g., corresponding to the terminal structure 132a of the terminal structures 132) configured to carry a first supply voltage, a second power node (e.g., corresponding to the terminal structure 132b of the terminal structures 132) configured to carry a second supply voltage, and a third power node (e.g., corresponding to the terminal structure 132c of the terminal structures 132) configured to carry a third supply voltage. In some aspects, the first supply voltage may have a first voltage level, the second supply voltage may have a second voltage level different from the first voltage level, and the third supply voltage may have a ground voltage level or a third voltage level different from the first voltage level and the second voltage level. In some aspects, the third supply voltage may be the ground voltage level, the second voltage level may be greater than the ground voltage level and may range from 1.5 V to 2.5 V. In some aspects, the first voltage level may be greater than the second voltage level and may range from 5 V to 12 V.

In some aspects, the PMIC 130 may be configured to receive the first supply voltage at the terminal structure 132a through a conductive path 112 formed by various conductive patterns in the PCB 110. In some aspects, the PMIC 130 may be configured to output the second supply voltage at the terminal structure 132b to a terminal structure 122a of the terminal structures 122 of the IC package 120 through a conductive path 114 formed by various conductive patterns in the PCB 110. In some aspects, the PMIC 130 may be configured to carry the third supply voltage at the terminal structure 132c, which is also electrically shared by another terminal structure of the terminal structures 122 of the IC package 120 through another conductive path (not shown) formed by various conductive patterns in the PCB 110.

In some aspects, the second IC die 160 may be configured as an IVR and configured to receive the second supply voltage through a conductive path formed by various conductive patterns in the package substrate 124 and output a fourth supply voltage to the first IC die 150 through another conductive path formed by various conductive patterns in the package substrate 124. In some aspects, the fourth supply voltage may be greater than the ground voltage level and may range from 0.7 V to 1.0 V. In some aspects, the first IC die 150 may be energized based on a voltage difference between the fourth supply voltage and the third supply voltage (e.g., at the ground voltage level).

In some aspects, the capacitive device 142 and the inductive device 144 may be compatible with a form factor of an surface mounted device (SMD). In some aspects, the capacitive device 142 may be electrically coupled to the conductive path 114 carrying the second supply voltage (e.g., between the conductive path 114 carrying the second supply voltage and another conductive path carrying the third supply voltage) in order to stabilize a direct current (DC) voltage level of the second supply voltage. In some examples, the inductive device 144 may be electrically coupled to the conductive path 114 carrying the internal supply voltage (e.g., connected to the conductive path 114 in series) in order to reduce the non-DC noises of (or coupled to by cross-talking) the second supply voltage.

In some aspects, the inductive device 144 would be preferrable to have a high inductance (e.g., greater than 10 nanohenries (nH)), low DC resistance (e.g., less than 10 microohms (mΩ)), low manufacture complexity and costs, and consistent with the form factor of an SMD for backward compatibility with existing PCB layout designs and minimized costs for switching parts for mass production.

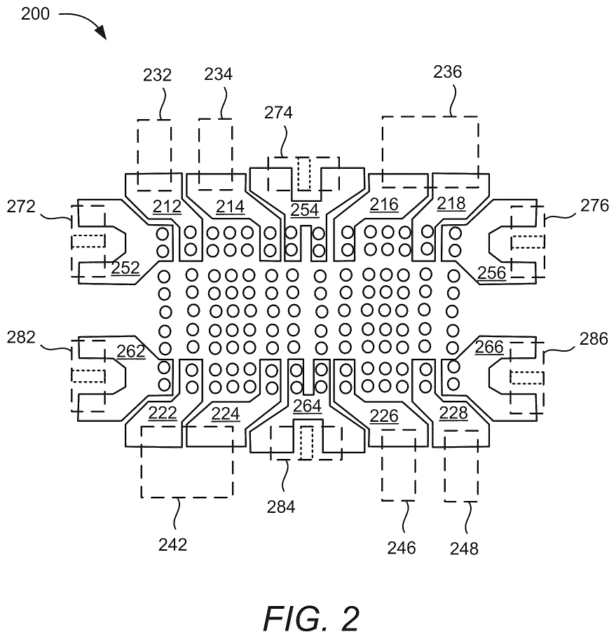

FIG. 2 is a simplified layout view of a portion of a layout pattern 200 of a circuit board (e.g., the PCB 110 in FIG. 1), according to aspects of the disclosure. In some aspects, the layout pattern 200 shows circles (not labeled) representing where the terminal structures (e.g., the terminal structures 132 in FIG. 1) of a PMIC (e.g., the PMIC 130 in FIG. 1) may be mounted on the circuit board.

As shown in FIG. 2, the layout pattern 200 may include conductive patterns 212, 214, 216, 218, 222, 224, 226, and 228 representing the conductive structures to which respective inductive devices 232, 234, 236, 242, 246, and 248 may be connected. In this non-limiting example, each one of the inductive devices 232, 234, 246, and 248 may have an inductor implemented therein; and each one of the inductive the inductive devices 236 and 242 may include two inductors implemented therein. In some aspects, each of the inductive devices 232, 234, 236, 242, 246, and 248 may correspond to the inductive device 144 in FIG. 1.

As shown in FIG. 2, the layout pattern 200 may include conductive patterns 252, 254, 256, 262, 264, and 266 representing the conductive structures to which respective capacitive devices 272, 274, 276, 282, 284, and 286 may be connected. In this non-limiting example, each one of the capacitive devices 272, 274, 276, 282, 284, and 286 may have a capacitor implemented therein. In some aspects, each of the capacitive devices 272, 274, 276, 282, 284, and 286 may correspond to the capacitive device 142 in FIG. 1.

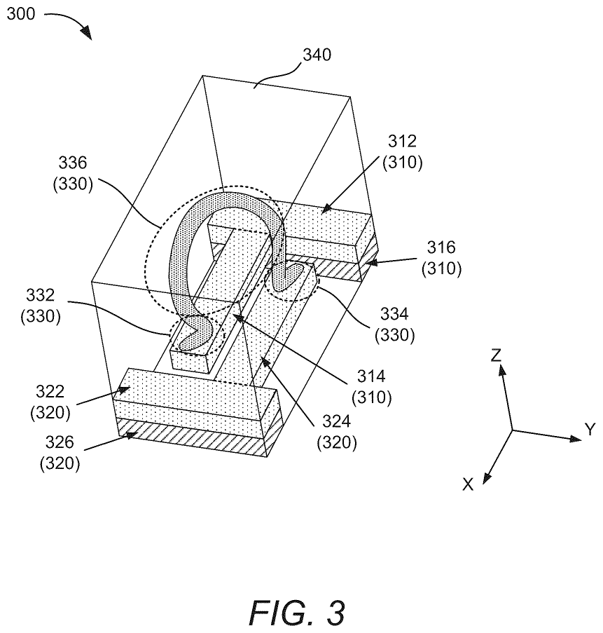

FIG. 3 is a simplified perspective view of an example inductive device 300, according to aspects of the disclosure. In some aspects, FIG. 3 is a simplified perspective view of inductive device 300, and certain details and components of the inductive device 300 may be simplified or not depicted in FIG. 3. In some aspects, to more clearly describe the structure of the inductive device 300, certain features may be depicted as being transparent in order to reveal one or more other features that may otherwise be visually blocked. Also, the directions X, Y, and Z are depicted as references regarding the spatial relationship among various components of the inductive device 300.

In some aspects, the inductive device 300 may include an inductor implemented therein and may correspond to any the inductive devices 232, 234, 246, and 248 in FIG. 2. As shown in FIG. 3, the inductive device 300 may include a first conductive structure 310, a second conductive structure 320, and a bond-wire structure 330. In some aspects, the first conductive structure 310 may include a first anchor portion 312 and a first elongated portion 314. In some aspects, the first elongated portion 314 may have a first end portion and a second end portion, where the first elongated portion 314 is coupled to the first anchor portion 312 at the first end portion. Also, the second conductive structure 320 may include a second anchor portion 322 and a second elongated portion 324. In some aspects, the second elongated portion 324 may have a third end portion and a fourth end portion, where the second elongated portion 324 is coupled to the second anchor portion 322 at the third end portion. In some aspects, the first conductive structure 310 may further include a first terminal portion 316 under the first anchor portion 312. In some aspects, the second conductive structure 320 may further include a second terminal portion 326 under the second anchor portion 322. In some aspects, the first conductive structure 310 and the second conductive structure 320 may include copper, aluminum, or a combination thereof.

In some aspects, the bond-wire structure 330 may have a first bottom portion 332, a second bottom portion 334, and an arch portion 336 between the first bottom portion 332 and the second bottom portion 334. In some aspects, the first bottom portion 332 may be mounted on the second end portion of the first elongated portion 314, and the second bottom portion 334 may be mounted on the fourth end portion of the second elongated portion 324. In some aspects, the arch portion 336 may have a wire diameter greater than 75 micrometers (μm). In some aspects, the bond-wire structure 330 may include gold, copper, aluminum, silver, or any combination thereof.

In some aspects, the inductive device 300 may include a inductor. In some aspects, the first anchor portion 312 may correspond to a first terminal of the inductor of the inductive device 300, and the second anchor portion 322 may correspond to a second terminal of the inductor of the inductive device 300. In some aspects, a coil structure of the inductor of the inductive device 300 may include the arch portion 336, the first elongated portion 314, and the second elongated portion 324.

Moreover, in some aspects, the inductive device 300 may further include a magnetic molding portion 340 over the first conductive structure 310 and the second conductive structure 320 and filling at least a portion of an inner space (e.g., an aperture) of the coil structure defined based on the arch portion 336, the first elongated portion 314, and the second elongated portion 324. In some aspects, the magnetic molding portion 340 may cover the first conductive structure 310, the second conductive structure 320, and the bond-wire structure 330. In some aspects, the magnetic molding portion 340 may include a material with a relative magnetic permeability of at least 19 at 100 MHz. In some aspects, the magnetic molding portion 340 may include a resin material or a ceramic material, together with one or more elements including carbon, silicon, chromium, iron, platinum, phosphorus, or any combination thereof. In some aspects, to more clearly describe the structure of the inductive device 300, the magnetic molding portion 340 is depicted in FIG. 3 as being transparent in order to reveal one or more other features that may otherwise be visually blocked.

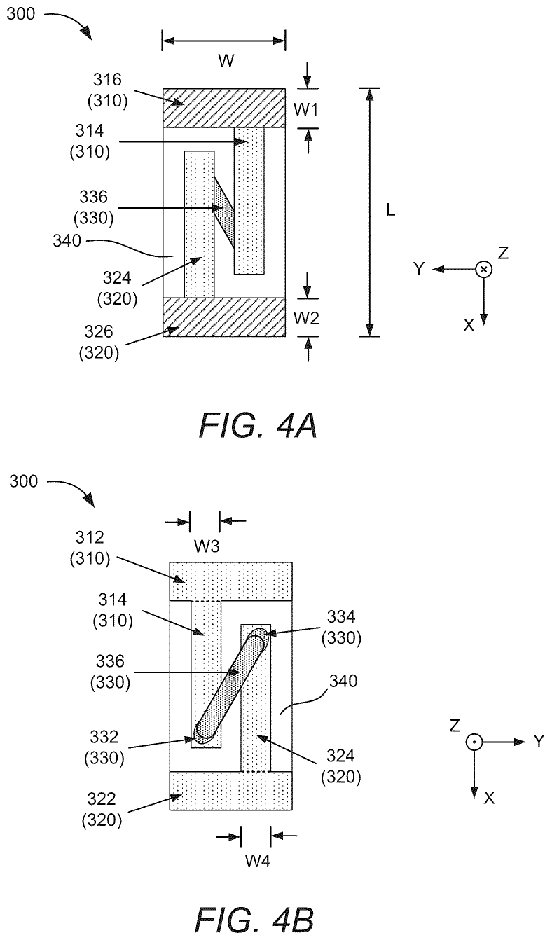

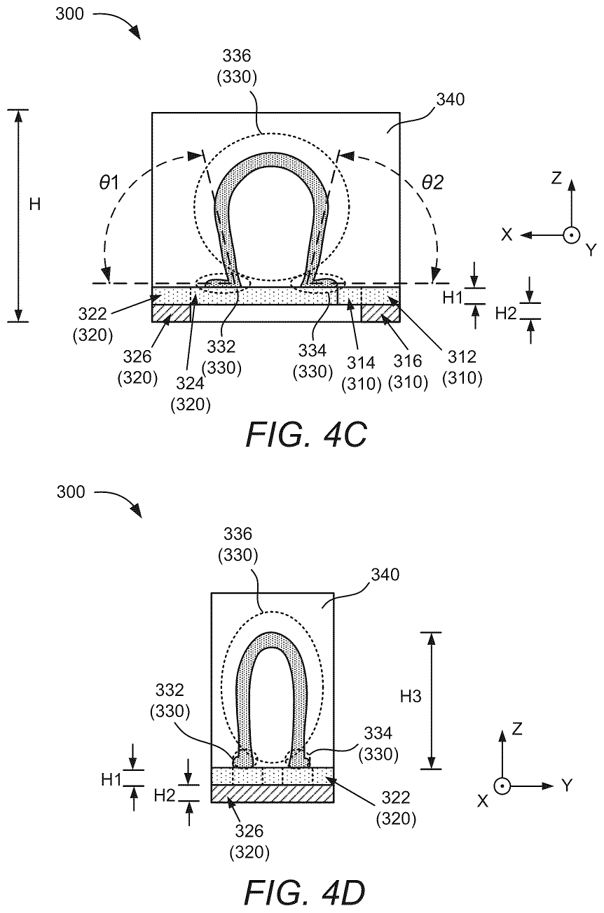

FIG. 4A shows a bottom view of the example inductive device 300 of FIG. 3 (from below the inductive device 300 looking at the Z direction), according to aspects of the disclosure. Also, FIG. 4B shows a top view of the example inductive device 300 of FIG. 3 (from above the inductive device 300 looking at the inverted Z direction), according to aspects of the disclosure. In some aspects, the components depicted in FIGS. 4A-4B that are the same as those in FIG. 3 are given the same reference numbers, and detailed description thereof may be simplified or omitted. In some aspects, to more clearly describe the structure of the inductive device 300, the magnetic molding portion 340 is depicted as being transparent in order to reveal one or more other features that may otherwise be visually blocked.

As shown in FIGS. 4A and 4B, the first elongated portion 314 and the second elongated portion 324 may be disposed in parallel with a first direction (e.g., direction X). In some aspects, the first elongated portion 314 and the second elongated portion 324 may be separated from each other along a second direction (e.g., direction Y) different from the first direction. In the non-limiting example illustrated in the present disclosure, the first elongated portion 314 and the second elongated portion 324 may have a rectangular shape and arranged in perpendicular to the first anchor portion 312 and the second anchor portion 322. In some aspects, the first elongated portion 314 and the second elongated portion 324 may have a curved shape or a trapezoid shape, and may be arranged not perpendicular to the first anchor portion 312 and/or the second anchor portion 322.

In some aspects, with reference to FIG. 4A, the inductive device 300 may be configured to be compatible with a form factor of an SMD. In some aspects, the inductive device 300 may have a length L of about 1 millimeter (mm) and a width of about 0.5 mm. In some aspects, the width W1 of the first terminal portion 316 and the width W2 of the second terminal portion 326 may be set in consistent with the form factor of the SMD regarding the sizes and positions of contact terminals thereof.

In some aspects, with reference to FIG. 4B, increasing the diameter of the bond-wire structure 330, the width W3 of the first elongated portion 314, and the width W4 of the second elongated portion 324 may reduce the DC resistance of the inductor formed based on the bond-wire structure 330, the first elongated portion 314, and the second elongated portion 324. Therefore, one consideration regarding setting the diameter of the bond-wire structure 330, the width W3 of the first elongated portion 314, and/or the width W4 of the second elongated portion 324 may be as large as possible within the size limitations of the inductive device 300. As illustrated above, in some aspects, the arch portion 336 may have a wire diameter greater than 75 μm.

Moreover, in some aspects, as the bond-wire structure 330 may be mounted on the first elongated portion 314 and the second elongated portion 324 based on a wedge-bonding process, the dimensions of the first elongated portion 314 and the second elongated portion 324 (such as the width W3 of the first elongated portion 314 and the width W4 of the second elongated portion 324) may be set to be sufficient large to accommodate the landing of the first bottom portion 332 and the second bottom portion 334 of the bond-wire structure 330.

In some aspects, provided that the inductive device 300 may be configured to be not following a form factor of an SMD, the dimensions regarding the diameter of the bond-wire structure 330, the width W3 of the first elongated portion 314, and/or the width W4 of the second elongated portion 324 may be further enlarged in order to reduce the DC resistance of the inductor formed based on the bond-wire structure 330 and/or to increase the inductance value by increasing an aperture area of the coil structure.

FIG. 4C shows a side view of the example inductive device 300 of FIG. 3 (from a side of the inductive device 300 looking at the inverted Y direction), according to aspects of the disclosure. Also, FIG. 4D shows another side view of the example inductive device 300 of FIG. 3 (from another side the inductive device 300 looking at the inverted X direction), according to aspects of the disclosure. In some aspects, the components depicted in FIGS. 4C-4D that are the same as those in FIG. 3 are given the same reference numbers, and detailed description thereof may be simplified or omitted. In some aspects, to more clearly describe the structure of the inductive device 300, the magnetic molding portion 340 is depicted as being transparent in order to reveal one or more other features that may otherwise be visually blocked.

In some aspects, with reference to FIG. 4C, the inductive device 300 may be configured to be compatible with the form factor of the SMD, and the inductive device 300 may have a height H of about 0.65 mm. In some aspects, a size of the inner space (e.g., the aperture) of the coil structure defined based on the arch portion 336, the first elongated portion 314, and the second elongated portion 324 may be limited by the height H. In some aspects, provided that the inductive device 300 may be configured to be not following a form factor of an SMD, the dimensions of the size of the inner space of the coil structure may be set based on the designed inductance value, and the height H may then be defined accord to the size of the inner space of the coil structure.

Moreover, in some aspects, as the bond-wire structure 330 may be mounted on the first elongated portion 314 and the second elongated portion 324 based on a wedge-bonding process, a first angle θ1 defined by the first bottom portion 332 and the arch portion 336 may be less than 90 degrees, and/or a second angle θ2 defined by the second bottom portion 334 and the arch portion 336 may be less than 90 degrees.

In some aspects, with reference to FIGS. 4C-4D, the inductive device 300 may be configured to be compatible with the form factor of the SMD, the first anchor portion 312 and/or the second anchor portion 322 may have a thickness H1 of about 75 μm, and the first terminal portion 316 and/or the second terminal portion 326 may have a thickness H2 of about 75 μm. In some aspects in this non-limiting example, the arch portion 336 may have a height H3 of about 400 μm above an upper surface of the first elongated portion 314 and the second elongated portion 324.

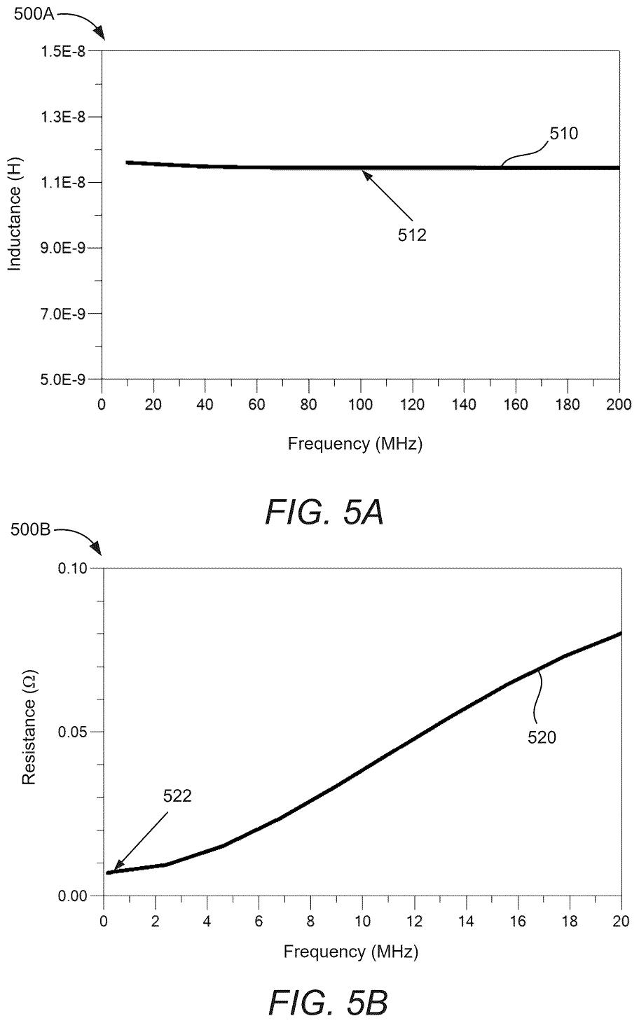

FIG. 5A is a diagram 500A showing the inductance value (illustrated by the vertical axis in Henries, H) of the inductor of the example inductive device 300 of FIG. 3 over the frequency (illustrated by the horizontal axis in megahertz, MHz), as represented by curve 510. FIG. 5B is a diagram 500B showing the resistance value (illustrated by the vertical axis in Ohms, Ω) of the inductor of the example inductive device 300 of FIG. 3 over the frequency (illustrated by the horizontal axis in megahertz, MHz), as represented by curve 520. In this non-limiting example, as indicated at point 512 of the curve 510, the inductor of the inductive device 300 may have an inductance value of about 11.4 nH at about 100 MHz. In this non-limiting example, as indicated at point 522 of the curve 520, the inductor of the inductive device 300 may have a resistance value of about 7.5 mΩ at about 0.2 MHz (or 200 kilohertz, kHz).

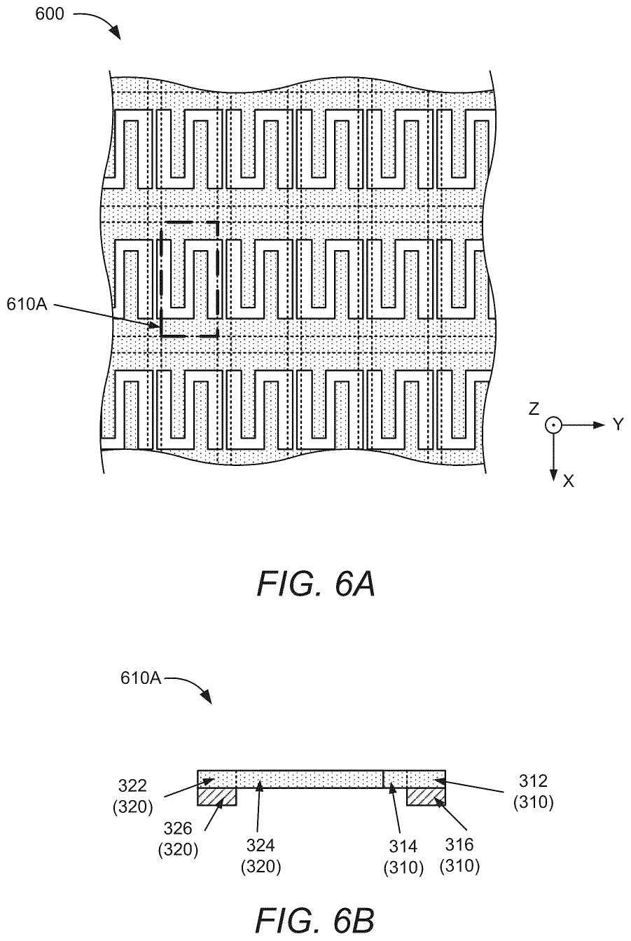

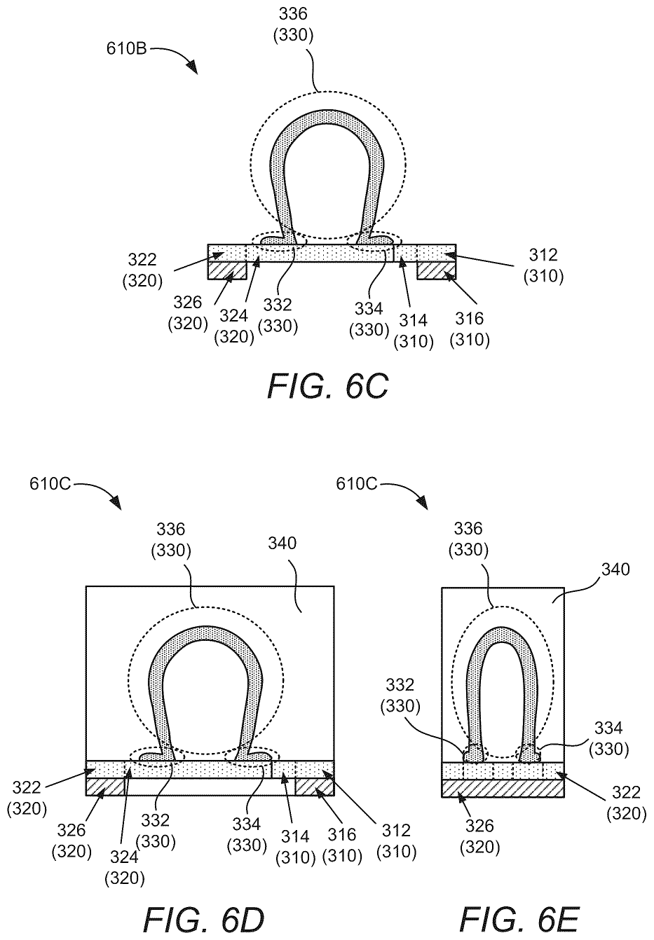

FIGS. 6A-6E illustrate structures at various stages of manufacturing the example inductive device 300 of FIG. 3, according to aspects of the disclosure. The components illustrated in FIGS. 6A-6E that are the same or similar to those of FIG. 3 are given the same reference numbers, and the detailed description thereof may be simplified or omitted.

FIG. 6A shows a top view of a patterned conductive plate 600, according to aspects of the disclosure. In some aspect, the patterned conductive plate 600 may include an array of structure 610A, which may correspond to a patterned unit structure that includes a first conductive structure 310 and a second conductive structure 320 as illustrated in FIG. 3 and further illustrated in FIG. 6B.

FIG. 6B shows a side view of the structure 610A, according to aspects of the disclosure. In some aspects, a bottom view of the structure 610A may correspond to FIG. 4A, without the bond-wire structure 330 and the magnetic molding portion 340. In some aspects, a top view of the structure 610A may correspond to FIG. 4B, without the bond-wire structure 330 and the magnetic molding portion 340.

At this stage, the structure 610A may be part of the patterned conductive plate 600 and may still be physically connected to other patterned unit structure. At this stage, the structure 610A may include a first conductive structure 310 and a second conductive structure 320. In some aspects, the first conductive structure 310 may include a first anchor portion 312 and a first elongated portion 314. Also, the second conductive structure 320 may include a second anchor portion 322 and a second elongated portion 324. In some aspects, the first conductive structure 310 may further include a first terminal portion 316 under the first anchor portion 312. In some aspects, the second conductive structure 320 may further include a second terminal portion 326 under the second anchor portion 322.

In some aspects, the first conductive structure 310 and the second conductive structure 320 may be formed based on performing two half-etching processes on a conductive plate. In some aspects, the first anchor portion 312, the first elongated portion 314, the second anchor portion 322, and the second elongated portion 324 may be formed based on a first half-etching process from a first side of the conductive plate. In some aspects, the first terminal portion 316 and the second terminal portion 326 may be formed based on a second half-etching process from a second side of the conductive plate. In some aspects, the conductive plate (and hence the first conductive structure 310 and the second conductive structure 320) may include copper, aluminum, or a combination thereof.

In some aspects, the first anchor portion 312 and/or the second anchor portion 322 may have a thickness of about 75 μm, and the first terminal portion 316 and/or the second terminal portion 326 may have a thickness of about 75 μm.

FIG. 6C shows a side view of the structure 610B, according to aspects of the disclosure. As shown in FIG. 6C, a structure 610B may be formed based on the structure 610A. In some aspects, a bottom view of the structure 610B may correspond to FIG. 4A, without the magnetic molding portion 340. In some aspects, a top view of the structure 610B may correspond to FIG. 4B, without the magnetic molding portion 340.

In some aspects, the structure 610B may be formed based on mounting a first bottom portion 332 of a bond-wire structure 330 on the first conductive structure 310 that has a first anchor portion 312 and a first elongated portion 314; and mounting a second bottom portion 334 of the bond-wire structure 330 on the second conductive structure 320 that has a second anchor portion 322 and a second elongated portion 324. In some aspects, the first anchor portion 312 may correspond to a first terminal of an inductor of the resulting inductive device. In some aspect, the first elongated portion 314 may have a first end portion and a second end portion, where the first elongated portion 314 is coupled to the first anchor portion 312 at the first end portion. In some aspects, the second anchor portion 322 may correspond to a second terminal of the inductor of the resulting inductive device. In some aspects, the second elongated portion 324 may have a third end portion and a fourth end portion where the second elongated portion 324 is coupled to the second anchor portion 322 at the third end portion.

In some aspects, the bond-wire structure 330 may further include an arch portion 336 between the first bottom portion 332 and the second bottom portion 334. In some aspects, the first bottom portion 332 may be mounted on the second end portion of the first elongated portion 314, and the second bottom portion 334 may be mounted on the fourth end portion of the second elongated portion 324. In some aspects, a coil structure of the inductor of the resulting inductive device may include the arch portion 336, the first elongated portion 314, and the second elongated portion 324.

In some aspects, the mounting the first bottom portion 332 of the bond-wire structure 330 and the mounting the second bottom portion 334 of the bond-wire structure 330 may be based on a wedge-bonding process. In some aspects, the arch portion 336 may have a wire diameter greater than 75 μm. In some aspects, the bond-wire structure 330 may include gold, copper, aluminum, silver, or any combination thereof. In some aspects, the arch portion 336 may have a height of about 400 μm above an upper surface of the first elongated portion 314 and the second elongated portion 324.

FIGS. 6D-6E show side views of the structure 610C from two different sides, according to aspects of the disclosure. As shown in FIGS. 6D-6E, a structure 610C may be formed based on the structure 610B. In some aspects, a bottom view of the structure 610C may correspond to FIG. 4A. In some aspects, a top view of the structure 610C may correspond to FIG. 4B.

In some aspects, the structure 610C may be formed based on forming a magnetic molding portion 340 over the first conductive structure 310 and the second conductive structure 320 and filling at least a portion of an inner space of the coil structure. In some aspects, the magnetic molding portion 340 may include a material with a relative magnetic permeability of at least 19 at 100 MHz. In some aspects, the magnetic molding portion may include a resin material or a ceramic material, together with one or more elements including carbon, silicon, chromium, iron, platinum, phosphorus, or any combination thereof.

At this stage, the structure 610C may still be connected to other similarly formed inductive structure based on the patterned conductive plate 600, with a layer of magnetic molding material disposed thereon. In some aspects, an individual inductive device (e.g., the inductive device 300 in FIG. 3) may be separated from the array of inductive devices based on a dicing process. The structure 610C after being separated from the array of inductive devices may correspond to the inductive device 300 as illustrated in FIGS. 3-4D.

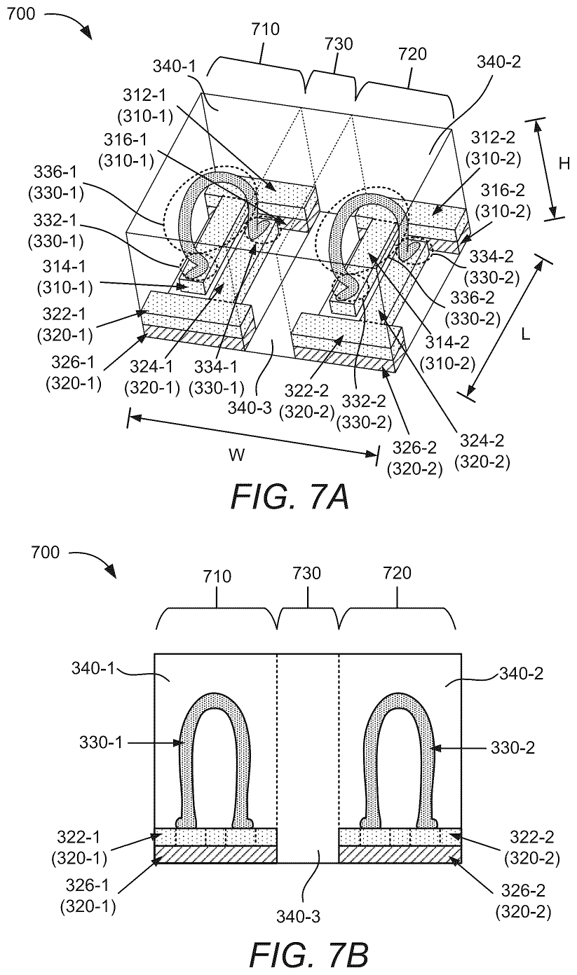

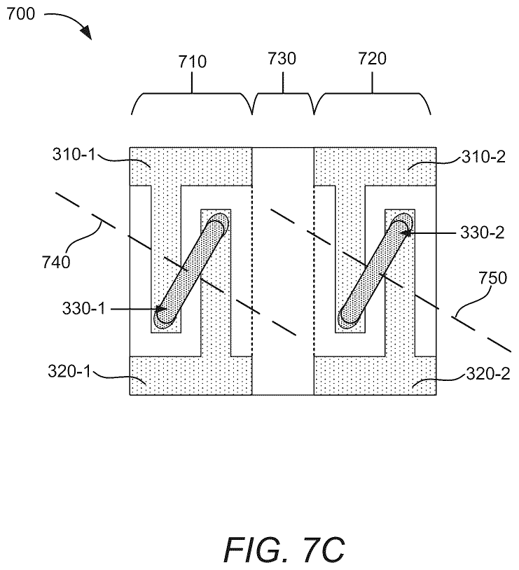

FIG. 7A is a simplified perspective view of another example inductive device 700, according to aspects of the disclosure. In some aspects, FIG. 7A is a simplified perspective view of inductive device 700, and certain details and components of the inductive device 700 may be simplified or not depicted in FIG. 7A. In some aspects, to more clearly describe the structure of the inductive device 700, certain features may be depicted as being transparent in order to reveal one or more other features that may otherwise be visually blocked.

In some aspects, the inductive device 700 may include two inductors implemented therein and may correspond to any the inductive devices 236 and 242 in FIG. 2. In some aspects, the inductive device 700 may be deemed as a variation of the inductive device 300. As shown in FIG. 7A, the inductive device 700 may include a first part 710 and a second part 720 each having a structure corresponding to the inductive device 300 in FIG. 3A. In some aspects, the inductive device 700 may further include a third part 730 connecting the first part 710 and the second part 720.

In some aspects, the first part 710 may include a first conductive structure 310-1 having a first anchor portion 312-1 and a first elongated portion 314-1, the first anchor portion 312-1 corresponding to a first terminal of a first inductor of the inductive device 700; a second conductive structure 320-1 having a second anchor portion 322-1 and a second elongated portion 324-1, the second anchor portion 322-1 corresponding to a second terminal of the first inductor of the inductive device 700; and a first bond-wire structure 330-1 having a first bottom portion 332-1, a second bottom portion 334-1, and a first arch portion 336-1 between the first bottom portion 332-1 and the second bottom portion 334-1. In some aspects, the first bottom portion 332-1 may be mounted on the first elongated portion 314-1, and the second bottom portion 334-1 may be mounted on the second elongated portion 324-1. In some aspects, a first coil structure of the first inductor of the inductive device 700 may include the first arch portion 336-1, the first elongated portion 314-1, and the second elongated portion 324-1.

In some aspects, the second part 720 may include a third conductive structure 310-2 having a third anchor portion 312-2 and a third elongated portion 314-2, the third anchor portion 312-2 corresponding to a third terminal of a second inductor of the inductive device 700; a fourth conductive structure 320-2 having a fourth anchor portion 322-2 and a fourth elongated portion 324-2, the fourth anchor portion 322-2 corresponding to a fourth terminal of the second inductor of the inductive device 700; and a second bond-wire structure 330-2 having a third bottom portion 332-2, a fourth bottom portion 334-2, and a second arch portion 336-2 between the third bottom portion 332-2 and the fourth bottom portion 334-2. In some aspects, the third bottom portion 332-2 may be mounted on the third elongated portion 314-2, and the fourth bottom portion 334-2 may be mounted on the fourth elongated portion 324-2. In some aspects, a second coil structure of the second inductor of the inductive device 700 may include the second arch portion 336-2, the third elongated portion 314-2, and the fourth elongated portion 324-2.

In some aspects, the first conductive structure 310-1 may further include a first terminal portion 316-1 under the first anchor portion 312-1; the second conductive structure 320-1 may further include a second terminal portion 326-1 under the second anchor portion 322-1. In some aspects, the third conductive structure 310-2 may further include a third terminal portion 316-2 under the third anchor portion 312-2; the fourth conductive structure 320-2 may further include a fourth terminal portion 326-2 under the fourth anchor portion 322-2.

In some aspects, the inductive device 700 may further include a magnetic molding portion (e.g., a combination of elements 340-1, 340-2, and 340-3) over the first conductive structure 310-1, the second conductive structure 320-1, the first coil structure, the third conductive structure 310-2, the fourth conductive structure 320-2, and the second coil structure. In some aspects, the magnetic molding portion may correspond to a portion of the first part 710 (e.g., the element 340-1), a portion of the second part 720 (e.g., the element 340-2), and the third part 730 (e.g., the element 340-3). In this non-limiting example, the inductive device 700 may have a width W of about 1.2 mm, a length L of about 1.0 mm, and a height H of about 0.65 mm.

In some aspects, the first conductive structure 310-1, the second conductive structure 320-1, and the first bond-wire structure 330-1, as well as the details thereof, may respectively correspond to the first conductive structure 310, the second conductive structure 320, and the bond-wire structure 330 in FIGS. 3-4D. In some aspects, the third conductive structure 310-2, the fourth conductive structure 320-2, and the second bond-wire structure 330-2, as well as the details thereof, may respectively correspond to the first conductive structure 310, the second conductive structure 320, and the bond-wire structure 330 in FIGS. 3-4D.

FIG. 7B shows a side view of the example inductive device 700 of FIG. 7A, according to aspects of the disclosure. The components depicted in FIG. 7B that are the same as those in FIG. 7A are given the same reference numbers, and detailed description thereof may be simplified or omitted. As shown in FIG. 7B in view of FIGS. 6A-6E, the inductive device 700 may be formed based on a manufacturing process similar to that illustrated with reference to FIGS. 6A-6E, except two inductors may be kept in one resulting device after the dicing process. In some aspects, the inductive device 700 may be usable to reduce the complexity and time for mounting two inductors to a circuit board.

FIG. 7C shows a top view of the example inductive device 700 of FIG. 7A, according to aspects of the disclosure. The components depicted in FIG. 7C that are the same as those in FIG. 7A are given the same reference numbers, and detailed description thereof may be simplified or omitted. In this non-limiting example, a first inductor based on the first part 710 of the inductive device 700 may include a self-inductance value of about 11.9 nH at 100 MHz; and a second inductor based on the second part 720 of the inductive device 700 may include a self-inductance value of about 11.9 nH at 100 MHz.

As shown in FIG. 7C, a first coil structure based on a bond-wire structure of the first part 710 may have a first aperture with a first normal reference line 740 passing the center of the first aperture, and a second coil structure based on a bond-wire structure of the second part 720 may have a second aperture with a second normal reference line 750 passing the center of the second aperture. As the coil structures are embedded in a magnetic molding material with a high magnetic permeability, the magnetic fields associated with the coil structures may mainly remain in the proximity of the respective coil structures. Also, the misalignment of the first normal reference line 740 and the second normal reference line 750 may also reduce the magnetic coupling between the two coil structures. In this non-limiting example, the first inductor based on the first part 710 and the second inductor based on the second part 720 may have a mutual-inductance value of about 0.07 nH at 100 MHz. In some aspects, the coupling coefficient between the first inductor and the second inductor may be about 0.6%, which may be negligible for the purposes of the inductive device 700 to be used in conjunction with a PMIC.

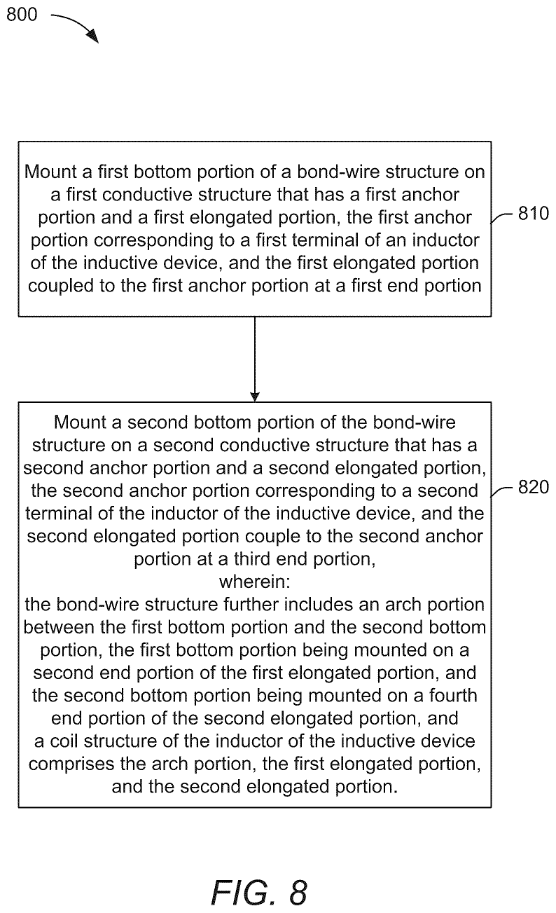

FIG. 8 illustrates a method 800 of manufacturing an inductive device (such as the inductive device 300 in FIG. 3 or the inductive device 700 in FIG. 7), according to aspects of the disclosure. In some aspects, FIGS. 6A-6E may show the structures at various stages of the method 800.

At operation 810, a first bottom portion (e.g., the first bottom portion 332 in FIG. 3) of a bond-wire structure (e.g., the bond-wire structure 330 in FIG. 3) may be mounted on a first conductive structure (e.g., the first conductive structure 310 in FIG. 3) that has a first anchor portion (e.g., the first anchor portion 312 in FIG. 3) and a first elongated portion (e.g., the first elongated portion 314 in FIG. 3). In some aspects, the first anchor portion may correspond to a first terminal of an inductor of the inductive device. In some aspects, the first elongated portion may be coupled to the first anchor portion at a first end portion.

At operation 820, a second bottom portion (e.g., the second bottom portion 334 in FIG. 3) of the bond-wire structure (e.g., the bond-wire structure 330 in FIG. 3) may be mounted on a second conductive structure (e.g., the second conductive structure 320 in FIG. 3) that has a second anchor portion (e.g., the second anchor portion 322 in FIG. 3) and a second elongated portion (e.g., the second elongated portion 324 in FIG. 3). In some aspects, the second anchor portion may correspond to a second terminal of the inductor of the inductive device. In some aspects, the second elongated portion may be coupled to the second anchor portion at a third end portion.

In some aspects, the bond-wire structure may further include an arch portion (e.g., the arch portion 336 in FIG. 3) between the first bottom portion and the second bottom portion. In some aspects, the first bottom portion may be mounted on a second end portion of the first elongated portion, and the second bottom portion may be mounted on a fourth end portion of the second elongated portion. In some aspects, a coil structure of the inductor of the inductive device may include the arch portion, the first elongated portion, and the second elongated portion.

In some aspects, the first conductive structure may further include a first terminal portion (e.g., the first terminal portion 316 in FIG. 3) under the first anchor portion, and the second conductive structure may further include a second terminal portion (e.g., the second terminal portion 326 in FIG. 3) under the second anchor portion. In some aspects, the method 800 may further include forming the first anchor portion, the first elongated portion, the second anchor portion, and the second elongated portion based on a first half-etching process from a first side of a conductive plate; and forming the first terminal portion and the second terminal portion based on a second half-etching process from a second side of the conductive plate.

In some aspects, the mounting the first bottom portion of the bond-wire structure and the mounting the second bottom portion of the bond-wire structure are based on a wedge-bonding process. In some aspects, the arch portion has a wire diameter greater than 75 μm. In some aspects, the bond-wire structure may include gold, copper, aluminum, silver, or any combination thereof.

In some aspects, the method 800 may further include forming a magnetic molding portion (e.g., the magnetic molding portion 340 in FIG. 3) over the first conductive structure and the second conductive structure and filling at least a portion of an inner space of the coil structure. In some aspects, the magnetic molding portion may include a resin material or a ceramic material, together with one or more elements including carbon, silicon, chromium, iron, platinum, phosphorus, or any combination thereof.

As will be appreciated, a technical advantage of the method 800 is to manufacture an inductive device that is compatible with the form factor of an SMD with at least comparable or greater inductance, reduced DC resistance, and reduced manufacturing complexity and/or costs. In some aspects, the inductive device may be formed without considering the form factor of an SMD, and the size of the inductive device may be adjusted in order to achieve a desirable inductance value and/or DC resistance value, and still with the reduced manufacturing complexity and/or costs.

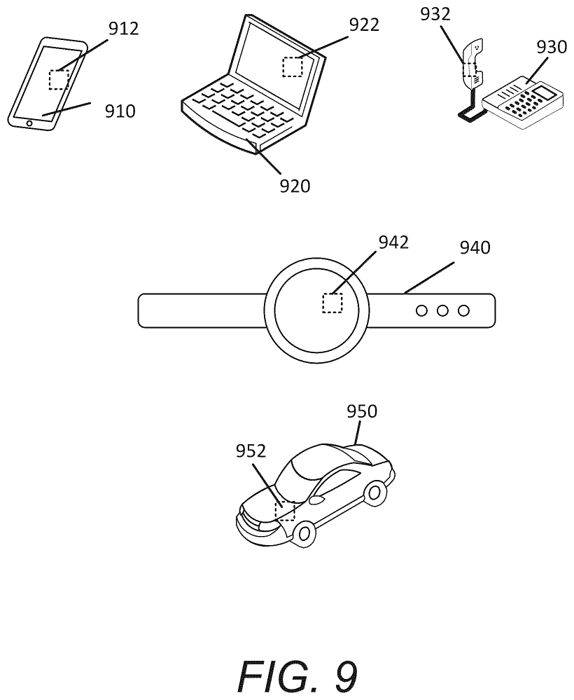

FIG. 9 illustrates various electronic devices that may include an inductive device described herein (such as the inductive device 300 in FIG. 3 or the inductive device 700 in FIG. 7), according to aspects of the disclosure. For example, a mobile phone device 910, a laptop computer device 920, a fixed location terminal device 930, a wearable device 940, or an electronic device onboard an automotive vehicle 950 may respectively include one or more inductive devices 912, 922, 932, 942, and 952 (e.g., corresponding to inductive devices to be used in association with respective PMICs). The devices 910, 920, 930, and 940 and the vehicle 950 illustrated in FIG. 9 are merely exemplary. Other apparatuses or devices that may feature one or more inductive devices as described herein may include, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. An inductive device, comprising: a first conductive structure having a first anchor portion and a first elongated portion, the first anchor portion corresponding to a first terminal of an inductor of the inductive device, and the first elongated portion coupled to the first anchor portion at a first end portion; a second conductive structure having a second anchor portion and a second elongated portion, the second anchor portion corresponding to a second terminal of the inductor of the inductive device, and the second elongated portion coupled to the second anchor portion at a third end portion; and a bond-wire structure having a first bottom portion, a second bottom portion, and an arch portion between the first bottom portion and the second bottom portion, the first bottom portion being mounted on a second end portion of the first elongated portion, and the second bottom portion being mounted on a fourth end portion of the second elongated portion, wherein: a coil structure of the inductor of the inductive device comprises the arch portion, the first elongated portion, and the second elongated portion.

Clause 2. The inductive device of clause 1, wherein: the arch portion has a wire diameter greater than 75 micrometers (μm).

Clause 3. The inductive device of any of clauses 1 to 2, wherein: the first elongated portion and the second elongated portion are disposed in parallel with a first direction, and the first elongated portion and the second elongated portion are separated from each other along a second direction different from the first direction.

Clause 4. The inductive device of any of clauses 1 to 3, further comprising: a magnetic molding portion over the first conductive structure and the second conductive structure and filling at least a portion of an inner space of the coil structure.

Clause 5. The inductive device of clause 4, wherein: the magnetic molding portion covers the first conductive structure, the second conductive structure, and the bond-wire structure.

Clause 6. The inductive device of any of clauses 4 to 5, wherein: the magnetic molding portion comprises a resin material or a ceramic material, together with one or more elements including carbon, silicon, chromium, iron, platinum, phosphorus, or any combination thereof.

Clause 7. The inductive device of any of clauses 1 to 6, wherein: the first conductive structure further includes a first terminal portion under the first anchor portion, and the second conductive structure further includes a second terminal portion under the second anchor portion.

Clause 8. The inductive device of any of clauses 1 to 7, wherein: the bond-wire structure comprises gold, copper, aluminum, silver, or any combination thereof.

Clause 9. The inductive device of any of clauses 1 to 8, wherein: a first angle defined by the first bottom portion and the arch portion is less than 90 degrees, a second angle defined by the second bottom portion and the arch portion is less than 90 degrees, or a combination thereof.

Clause 10. The inductive device of any of clauses 1 to 9, further comprising: a third conductive structure having a third anchor portion and a third elongated portion, the third anchor portion corresponding to a third terminal of a second inductor of the inductive device; a fourth conductive structure having a fourth anchor portion and a fourth elongated portion, the fourth anchor portion corresponding to a fourth terminal of the second inductor of the inductive device; and a second bond-wire structure having a third bottom portion, a fourth bottom portion, and a second arch portion between the third bottom portion and the fourth bottom portion, the third bottom portion being mounted on the third elongated portion, the fourth bottom portion being mounted on the fourth elongated portion, and a second coil structure of the second inductor of the inductive device comprising the second arch portion, the third elongated portion, and the fourth elongated portion; and a magnetic molding portion over the first conductive structure, the second conductive structure, the coil structure, the third conductive structure, the fourth conductive structure, and the second coil structure.

Clause 11. A method of manufacturing an inductive device, comprising: mounting a first bottom portion of a bond-wire structure on a first conductive structure that has a first anchor portion and a first elongated portion, the first anchor portion corresponding to a first terminal of an inductor of the inductive device, and the first elongated portion coupled to the first anchor portion at a first end portion; and mounting a second bottom portion of the bond-wire structure on a second conductive structure that has a second anchor portion and a second elongated portion, the second anchor portion corresponding to a second terminal of the inductor of the inductive device, and the second elongated portion coupled to the second anchor portion at a third end portion, wherein: the bond-wire structure further includes an arch portion between the first bottom portion and the second bottom portion, the first bottom portion being mounted on a second end portion of the first elongated portion, and the second bottom portion being mounted on a fourth end portion of the second elongated portion, and a coil structure of the inductor of the inductive device comprises the arch portion, the first elongated portion, and the second elongated portion.

Clause 12. The method of clause 11, wherein: the mounting the first bottom portion of the bond-wire structure and the mounting the second bottom portion of the bond-wire structure are based on a wedge-bonding process.

Clause 13. The method of any of clauses 11 to 12, wherein: the arch portion has a wire diameter greater than 75 micrometers (μm).

Clause 14. The method of any of clauses 11 to 13, further comprising: forming a magnetic molding portion over the first conductive structure and the second conductive structure and filling at least a portion of an inner space of the coil structure.

Clause 15. The method of clause 14, wherein: the magnetic molding portion comprises a resin material or a ceramic material, together with one or more elements including carbon, silicon, chromium, iron, platinum, phosphorus, or any combination thereof.

Clause 16. The method of any of clauses 11 to 15, wherein: the first conductive structure further includes a first terminal portion under the first anchor portion, the second conductive structure further includes a second terminal portion under the second anchor portion, and the method further comprises: forming the first anchor portion, the first elongated portion, the second anchor portion, and the second elongated portion based on a first half-etching process from a first side of a conductive plate; and forming the first terminal portion and the second terminal portion based on a second half-etching process from a second side of the conductive plate.

Clause 17. The method of any of clauses 11 to 16, wherein: the bond-wire structure comprises gold, copper, aluminum, silver, or any combination thereof.

Clause 18. An electronic device, comprising: an inductive device that comprises: a first conductive structure having a first anchor portion and a first elongated portion, the first anchor portion corresponding to a first terminal of an inductor of the inductive device, and the first elongated portion coupled to the first anchor portion at a first end portion; a second conductive structure having a second anchor portion and a second elongated portion, the second anchor portion corresponding to a second terminal of the inductor of the inductive device, and the second elongated portion coupled to the second anchor portion at a third end portion; and a bond-wire structure having a first bottom portion, a second bottom portion, and an arch portion between the first bottom portion and the second bottom portion, the first bottom portion being mounted on a second end portion of the first elongated portion, and the second bottom portion being mounted on a fourth end portion of the second elongated portion, wherein: a coil structure of the inductor of the inductive device comprises the arch portion, the first elongated portion, and the second elongated portion.

Clause 19. The electronic device of clause 18, wherein: the inductive device further comprises a magnetic molding portion over the first conductive structure and the second conductive structure and filling at least a portion of an inner space of the coil structure, and the magnetic molding portion covers the first conductive structure, the second conductive structure, and the bond-wire structure.

Clause 20. The electronic device of any of clauses 18 to 19, wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such. Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

What is claimed is:

1. An inductive device, comprising:
a first conductive structure having a first anchor portion and a first elongated portion, the first anchor portion corresponding to a first terminal of an inductor of the inductive device, and the first elongated portion coupled to the first anchor portion at a first end portion;
a second conductive structure having a second anchor portion and a second elongated portion, the second anchor portion corresponding to a second terminal of the inductor of the inductive device, and the second elongated portion coupled to the second anchor portion at a third end portion; and
a bond-wire structure having a first bottom portion, a second bottom portion, and an arch portion between the first bottom portion and the second bottom portion, the first bottom portion being mounted on a second end portion of the first elongated portion, and the second bottom portion being mounted on a fourth end portion of the second elongated portion,
wherein:
a coil structure of the inductor of the inductive device comprises the arch portion, the first elongated portion, and the second elongated portion.

2. The inductive device of claim 1, wherein:
the arch portion has a wire diameter greater than 75 micrometers (μm).

3. The inductive device of claim 1, wherein:
the first elongated portion and the second elongated portion are disposed in parallel with a first direction, and
the first elongated portion and the second elongated portion are separated from each other along a second direction different from the first direction.

4. The inductive device of claim 1, further comprising:
a magnetic molding portion over the first conductive structure and the second conductive structure and filling at least a portion of an inner space of the coil structure.

5. The inductive device of claim 4, wherein:
the magnetic molding portion covers the first conductive structure, the second conductive structure, and the bond-wire structure.

6. The inductive device of claim 4, wherein:
the magnetic molding portion comprises a resin material or a ceramic material, together with one or more elements including carbon, silicon, chromium, iron, platinum, phosphorus, or any combination thereof.

7. The inductive device of claim 1, wherein:
the first conductive structure further includes a first terminal portion under the first anchor portion, and
the second conductive structure further includes a second terminal portion under the second anchor portion.

8. The inductive device of claim 1, wherein:
the bond-wire structure comprises gold, copper, aluminum, silver, or any combination thereof.

9. The inductive device of claim 1, wherein:
a first angle defined by the first bottom portion and the arch portion is less than 90 degrees,
a second angle defined by the second bottom portion and the arch portion is less than 90 degrees, or
a combination thereof.

10. The inductive device of claim 1, further comprising:
a third conductive structure having a third anchor portion and a third elongated portion, the third anchor portion corresponding to a third terminal of a second inductor of the inductive device;
a fourth conductive structure having a fourth anchor portion and a fourth elongated portion, the fourth anchor portion corresponding to a fourth terminal of the second inductor of the inductive device; and
a second bond-wire structure having a third bottom portion, a fourth bottom portion, and a second arch portion between the third bottom portion and the fourth bottom portion, the third bottom portion being mounted on the third elongated portion, the fourth bottom portion being mounted on the fourth elongated portion, and a second coil structure of the second inductor of the inductive device comprising the second arch portion, the third elongated portion, and the fourth elongated portion; and
a magnetic molding portion over the first conductive structure, the second conductive structure, the coil structure, the third conductive structure, the fourth conductive structure, and the second coil structure.

11. A method of manufacturing an inductive device, comprising:
mounting a first bottom portion of a bond-wire structure on a first conductive structure that has a first anchor portion and a first elongated portion, the first anchor portion corresponding to a first terminal of an inductor of the inductive device, and the first elongated portion coupled to the first anchor portion at a first end portion; and
mounting a second bottom portion of the bond-wire structure on a second conductive structure that has a second anchor portion and a second elongated portion, the second anchor portion corresponding to a second terminal of the inductor of the inductive device, and the second elongated portion coupled to the second anchor portion at a third end portion,
wherein:
the bond-wire structure further includes an arch portion between the first bottom portion and the second bottom portion, the first bottom portion being mounted on a second end portion of the first elongated portion, and the second bottom portion being mounted on a fourth end portion of the second elongated portion, and
a coil structure of the inductor of the inductive device comprises the arch portion, the first elongated portion, and the second elongated portion.

12. The method of claim 11, wherein:
the mounting the first bottom portion of the bond-wire structure and the mounting the second bottom portion of the bond-wire structure are based on a wedge-bonding process.

13. The method of claim 11, wherein:
the arch portion has a wire diameter greater than 75 micrometers (μm).

14. The method of claim 11, further comprising:
forming a magnetic molding portion over the first conductive structure and the second conductive structure and filling at least a portion of an inner space of the coil structure.

15. The method of claim 14, wherein:
the magnetic molding portion comprises a resin material or a ceramic material, together with one or more elements including carbon, silicon, chromium, iron, platinum, phosphorus, or any combination thereof.

16. The method of claim 11, wherein:
the first conductive structure further includes a first terminal portion under the first anchor portion,
the second conductive structure further includes a second terminal portion under the second anchor portion, and
the method further comprises:
forming the first anchor portion, the first elongated portion, the second anchor portion, and the second elongated portion based on a first half-etching process from a first side of a conductive plate; and
forming the first terminal portion and the second terminal portion based on a second half-etching process from a second side of the conductive plate.

17. The method of claim 11, wherein:
the bond-wire structure comprises gold, copper, aluminum, silver, or any combination thereof.

18. An electronic device, comprising:
an inductive device that comprises:
a first conductive structure having a first anchor portion and a first elongated portion, the first anchor portion corresponding to a first terminal of an inductor of the inductive device, and the first elongated portion coupled to the first anchor portion at a first end portion;
a second conductive structure having a second anchor portion and a second elongated portion, the second anchor portion corresponding to a second terminal of the inductor of the inductive device, and the second elongated portion coupled to the second anchor portion at a third end portion; and
a bond-wire structure having a first bottom portion, a second bottom portion, and an arch portion between the first bottom portion and the second bottom portion, the first bottom portion being mounted on a second end portion of the first elongated portion, and the second bottom portion being mounted on a fourth end portion of the second elongated portion,
wherein:
a coil structure of the inductor of the inductive device comprises the arch portion, the first elongated portion, and the second elongated portion.

19. The electronic device of claim 18, wherein:
the inductive device further comprises a magnetic molding portion over the first conductive structure and the second conductive structure and filling at least a portion of an inner space of the coil structure, and
the magnetic molding portion covers the first conductive structure, the second conductive structure, and the bond-wire structure.

20. The electronic device of claim 18,
wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.
